(19) United States
(12) Patent Application Publication
(10) Pub. No.: US 2026/0025972 A1
(43) Pub. Date: Jan. 22, 2026

(54) Memory Circuitry And Methods Used In Forming Memory Circuitry

(71) Applicant: Micron Technology, Inc., Boise, ID (US)

(72) Inventors: Qitao Fu, Boise, ID (US); Dustin H. Brown, Boise, ID (US); Ruijing Ge, Boise, ID (US); David K. Hwang, Boise, ID (US)

(73) Assignee: Micron Technology, Inc., Boise, ID (US)

(21) Appl. No.: 19/231,966

(22) Filed: Jun. 9, 2025

Related U.S. Application Data
(60) Provisional application No. 63/674,172, filed on Jul. 22, 2024.

(51) Int. Cl. H10B 12/00

(52) U.S. Cl. CPC H10B 12/30; H10B 12/03; H10B 12/05

(57) ABSTRACT

Memory circuitry comprises vertically-alternating insulative tiers and memory-cell tiers. Memory cells in the memory cell tiers individually comprise a horizontal transistor having a gate, a capacitor side, and a digitline side. The capacitor is electrically coupled with the horizontal transistor on the capacitor side. A digitline is electrically coupled with the horizontal transistor on the digitline side. The insulative tiers comprise an insulative material that is vertically between immediately-vertically-adjacent of the memory-cell tiers. The insulative material extends laterally beyond the digitline side and the capacitor side of the gates of immediately-vertically-adjacent of the memory cells. The insulative material is vertically thinnest laterally outward of the digitline side of the gates than at the capacitor side of the gates. Methods are disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

Memory cells may be arranged or arrayed in several manners including, for example, in a vertical stack (e.g., along a z direction) comprising a three-dimensional (3D) memory array region having horizontal tiers in which individual memory cells are received (e.g., arrayed in x and y directions). The stack in the 3D memory array region comprises vertically-alternating insulative tiers and conductive tiers (e.g., as part of memory-cell tiers) that extend into a stair-step region. The stair-step region includes individual “stairs” (alternately termed “steps” or “stair-steps”) that define contact regions of conductive lines of individual of the conductive tiers to which vertical conductive vias can contact to provide electrical access to/from those conductive lines.

### BRIEF DESCRIPTION OF THE DRAWINGS

FIG. 1 is a diagrammatic schematic of a DRAM memory array and peripheral circuitry in accordance with the prior art and in accordance with an embodiment of the invention.

FIG. 2 is an enlargement of a portion of FIG. 1.

FIG. 3 is a diagrammatic cross-sectional view of a portion of a construction that will comprise circuitry in accordance with an embodiment of the invention.

FIGS. 4-21 are diagrammatic sequential sectional and/or enlarged views of the construction of FIG. 3, or portions thereof or alternate and/or additional embodiments, in process in accordance with some embodiments of the invention.

### DETAILED DESCRIPTION OF EXAMPLE EMBODIMENTS

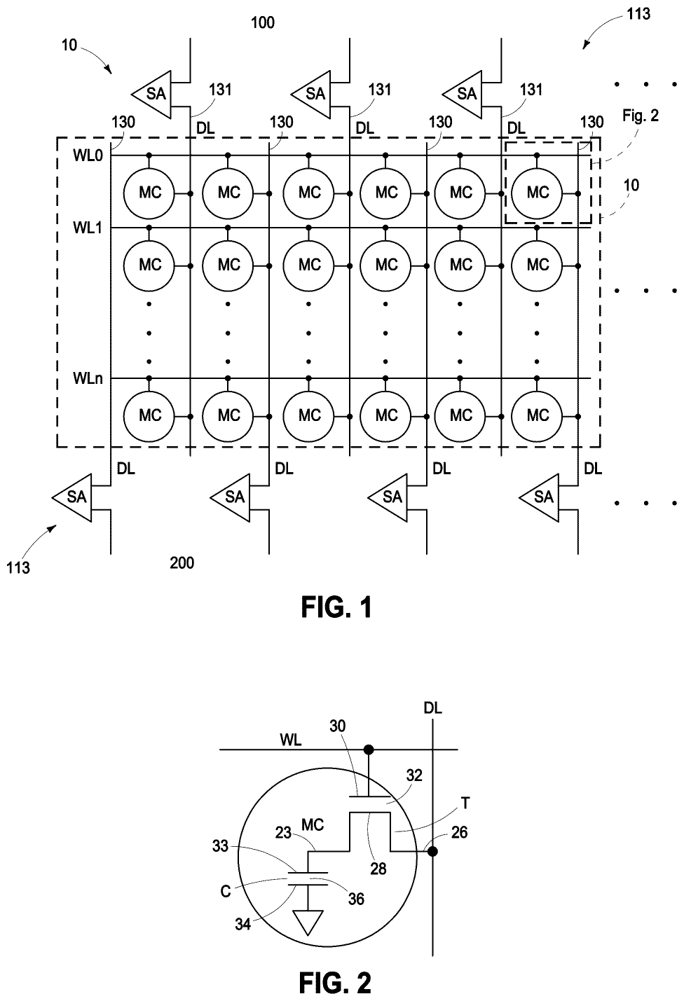

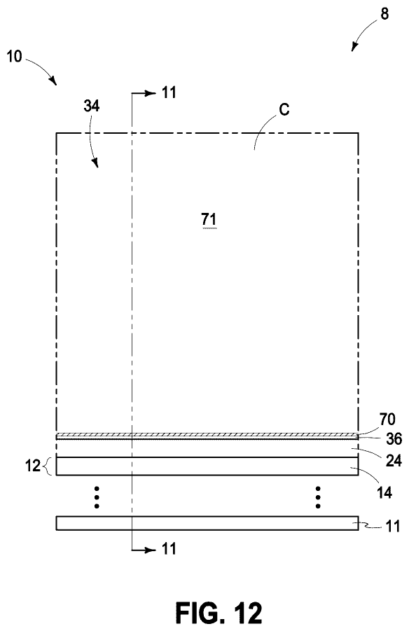

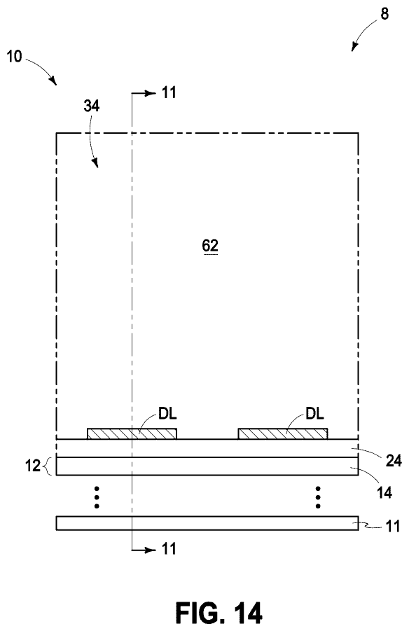

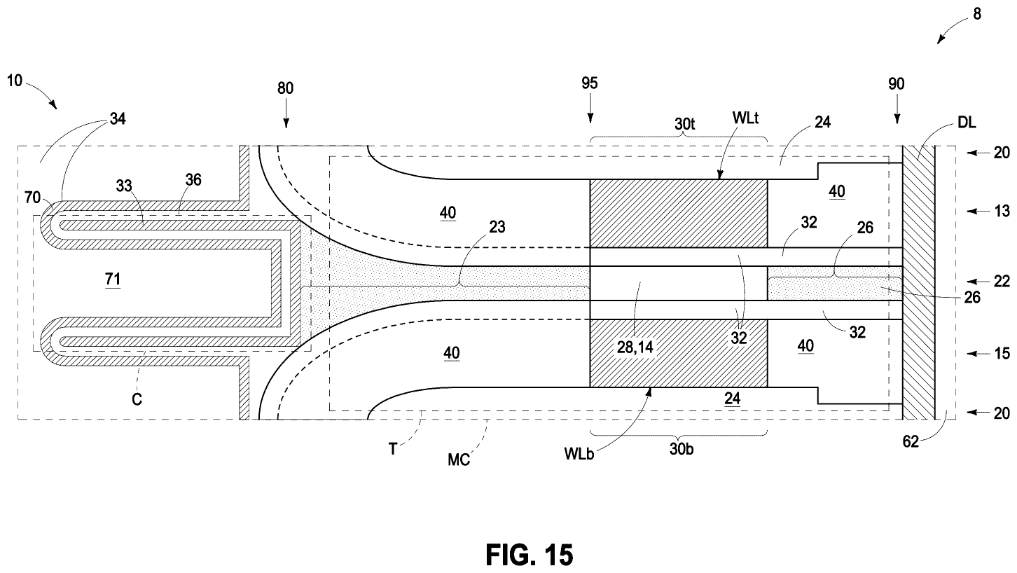

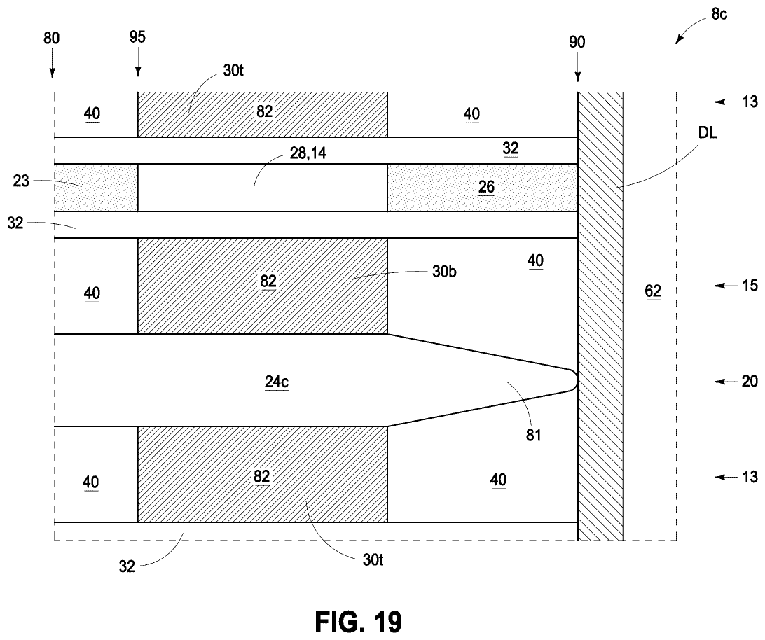

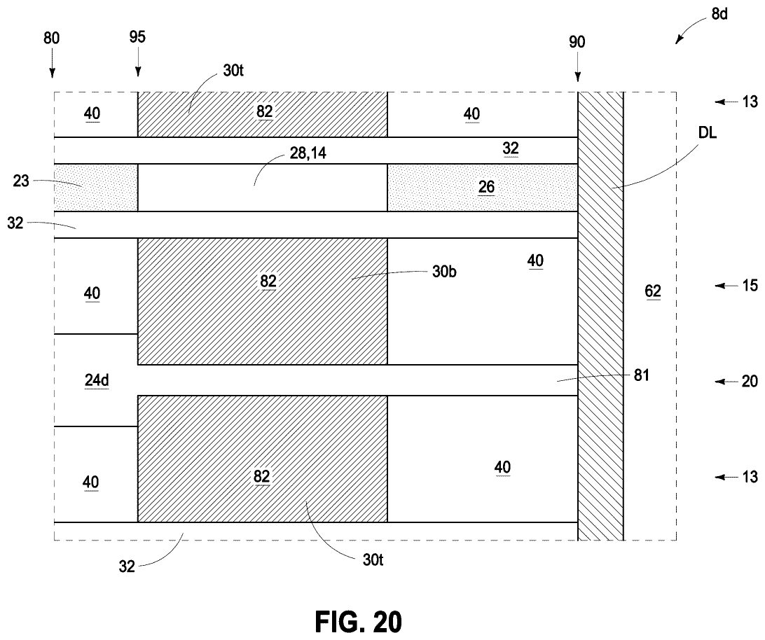

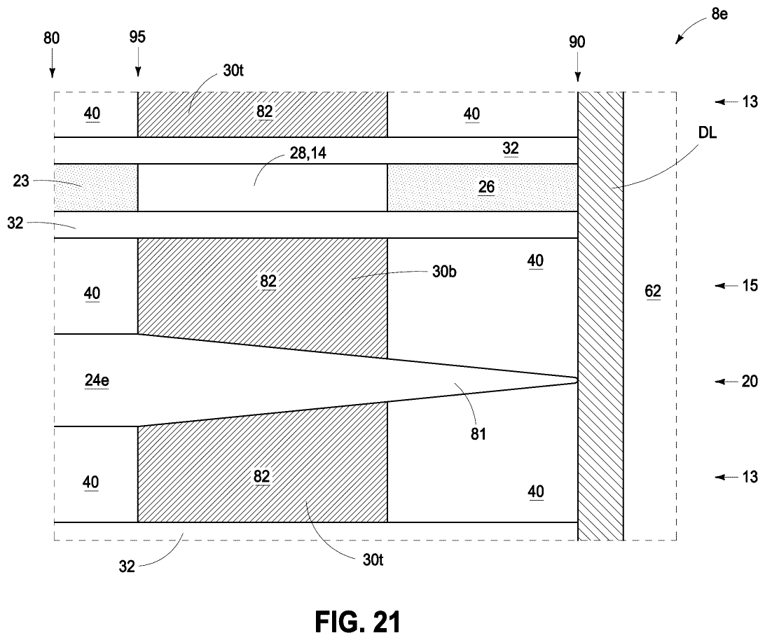

Embodiments of the invention encompass memory circuitry (e.g., DRAM) having vertically-alternating tiers of insulative material and memory cells, with the memory cells individually comprising a capacitor and a horizontally-oriented transistor. Embodiments of the invention also encompass methods used in forming such memory circuitry. Example method embodiments are first described with reference to FIGS. 1-21.

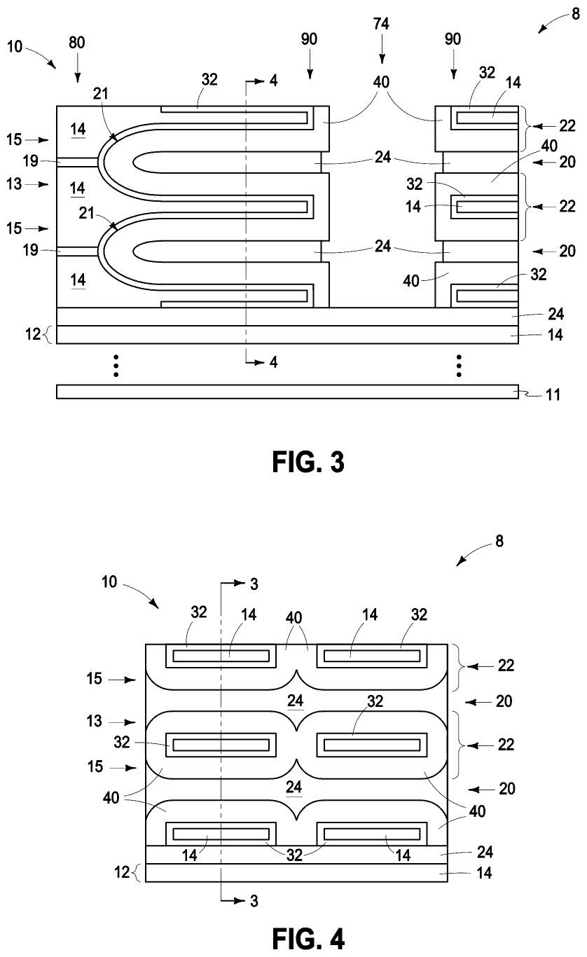

One example prior art schematic diagram of DRAM circuitry, and in accordance with an embodiment of the invention, is shown in FIGS. 1 and 2. FIG. 2 shows example memory cells MC individually comprising a transistor T and a capacitor C. One electrode of capacitor C is directly electrically coupled to a suitable potential (e.g., ground) and the other capacitor electrode is contacted with or comprises one of the source/drain regions of transistor T. The other source/drain region of transistor T is directly electrically coupled with a digitline/sense line 130 or 131 (also individually designated as DL). The gate of transistor T is directly electrically coupled with (e.g., comprises part thereof) a wordline/access line WL. FIG. 1 shows digitlines 130 and 131 extending from one of opposite sides 100 and 200 of a memory array area 10 into a peripheral circuitry area 113 that is aside memory array area 10. Digitlines 130 and 131 individually directly electrically couple with a sense amp SA on opposite sides 100 and 200 of array area 10 within peripheral circuitry area 113. Sense amps SA could be on only one side or all directly above or directly below memory array area 10. Non-schematic structure embodiments as shown herein in FIG. 3+ have the wordlines/access lines running horizontally and the digitlines/sense lines running vertically.

Referring to FIGS. 3 and 4, an example substrate construction 8 in process comprises an array or array area 10 that has been fabricated relative to a base substrate 11. Substrate 11 may comprise any one or more of conductive/conductor/conducting, semiconductive/semiconductor/semiconducting, and insulative/insulator/insulating (i.e., electrically herein) materials. Materials may be aside, elevationally inward, or elevationally outward of the FIGS. 3 and 4-depicted materials. For example, other partially or wholly fabricated components of integrated circuitry may be provided somewhere above, about, or within base substrate 11. Control and/or other peripheral circuitry for operating components within a memory array may also be fabricated and may or may not be wholly or partially within a memory array or sub-array. Further, multiple sub-arrays may also be fabricated and operated independently, in tandem, or otherwise relative one another. As used in this document, a “sub-array” may also be considered as an array. Example construction 8 comprises a semiconductor substrate 12 (e.g., a bulk wafer comprising monocrystalline silicon 14 and which may comprise base substrate 11) having insulative material 24 there-atop (e.g., silicon dioxide).

Construction 8 has been formed to comprise vertically-alternating insulative tiers 20 and memory-cell tiers 22. In a finished memory-circuitry construction, and in one embodiment, memory cells (not-yet-shown) of memory-cell tiers 22 individually comprise a horizontal transistor (not-yet-shown) having a top gate (not-yet-shown), a bottom gate (not-yet-shown), a capacitor side (e.g., 80), and a digitline side (e.g., 90). Insulative tiers 20 comprise an insulative material 24* (e.g., doped or undoped silicon dioxide) that is vertically between a top-gate tier 13 and a bottom-gate tier 15 of immediately-vertically-adjacent of memory-cell tiers 22 (an * being used as a suffix to be inclusive of all such same-numerically-designated structures or portions thereof that may or may not have other suffixes). Bottom-gate tier 15 and top-gate tier 13 comprise insulator material 40 (e.g., silicon nitride) of different composition from that of insulative material 24* and has insulative material 24* vertically there-between. Semiconductor material 14 is part of memory-cell tiers 22 and will comprise channel material and conductively-doped source/drain material of the horizontal transistors being formed. Semiconductor material 14 is indicated with the same numeral as material 14 of semiconductor substrate 12 although different semiconductor composition(s) therefrom may be used. Construction 8 may be formed by any suitable method. By way of example only, an example manner of forming construction 8 starts with forming alternating tiers of silicon material 14 and silicon-germanium material 19 having a horizontally-elongated trench 74 formed there-through. Through the trench, some of the silicon-germanium material is etched selectively relative to the tiers of silicon material 14. This is followed by etching of silicon material 14 of such tiers to thin it as shown and form cavities 21 vertically there-between. A gate insulator 32 (e.g., silicon dioxide, hafnium oxide, silicon nitride, etc.), insulator material 40, and insulative material 24* may then be formed through the trenches into cavities 21 and insulative material 24* etched back as shown to be removed from being over insulator material 40 in trenches 74.

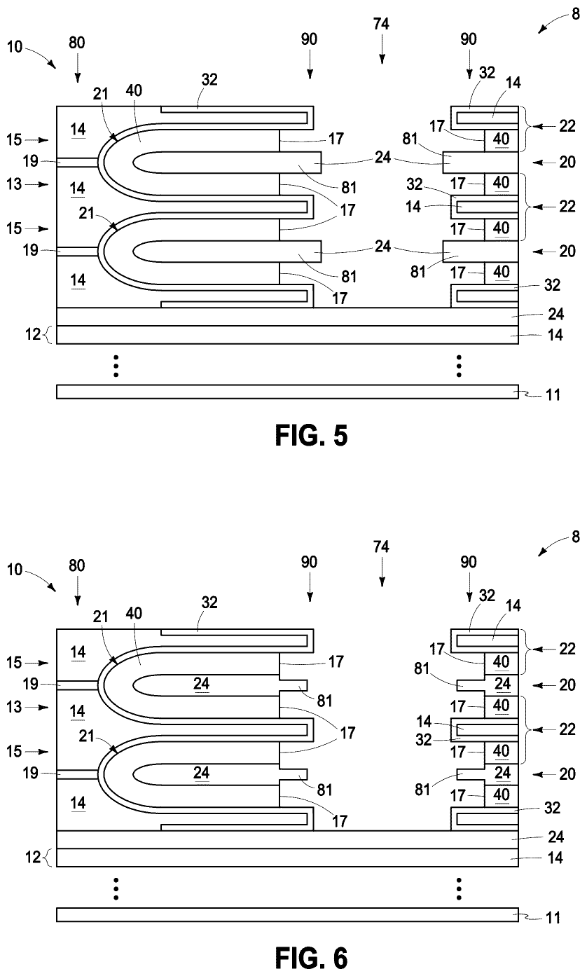

Referring to FIG. 5, insulator material 40 has been partially recessed (e.g., by isotropic etching; e.g., with H₃PO₄ if silicon nitride) such that a portion 81 of insulative material 24* projects laterally beyond digitline-side edges 17 of insulator material 40.

Referring to FIG. 6, that portion 81 of insulative material 24* that is laterally projecting beyond digitline-side edges 17 of insulator material 40 is removed (e.g., by etching; e.g., that is isotropic using HF if insulative material 24* is silicon dioxide) to reduce its vertical thickness (e.g., from the tops, bottoms, and ends of portion 81 as shown).

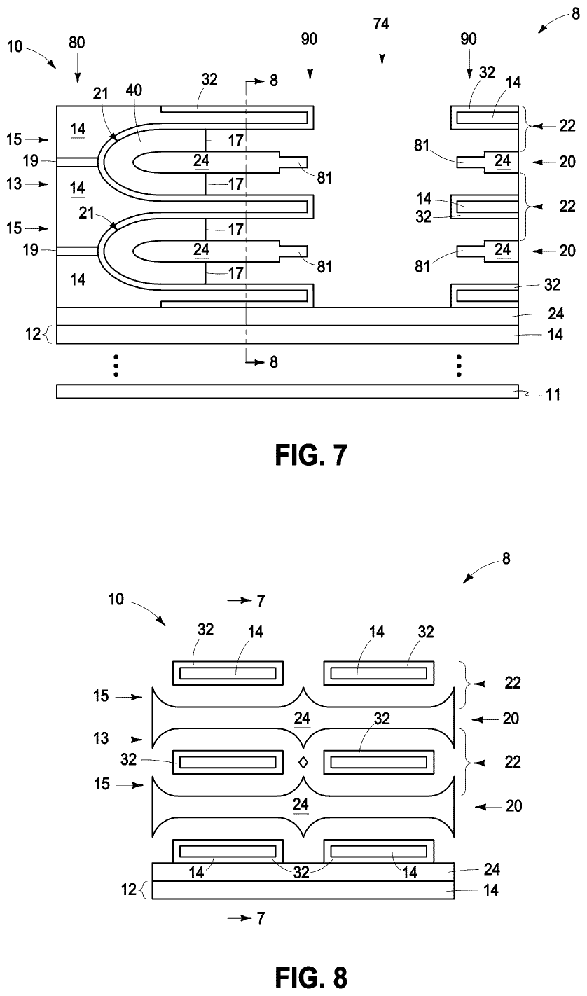

Referring to FIGS. 7 and 8, and after the example removing shown by FIG. 6, insulator material 40 has been laterally recessed toward capacitor side 80 selectively relative to insulative material 24* (e.g., by isotropic etching; e.g., using H₃PO₄ when insulator material 40 is silicon nitride and insulative material 24* is silicon dioxide).

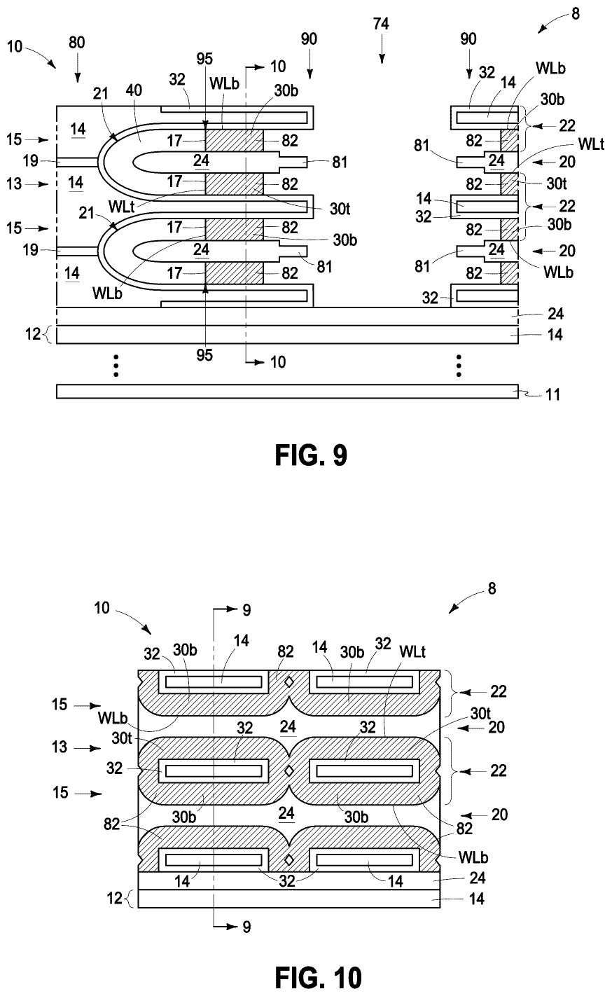

Referring to FIGS. 9 and 10, and after the example lateral recessing shown by FIGS. 7 and 8, conductive material 82 has been formed in top-gate tier 13 and in bottom-gate tier 15 of immediately-vertically-adjacent memory-cell tiers 22 to form a top gate 30t and a bottom gate 30b of a horizontal transistor T (e.g., at least source/drain regions thereof not having yet-been-formed). Construction 8 of FIGS. 9 and 10 may be formed, for example, by depositing conductive material 82 to fill the void-space shown in tiers 13 and 15 and line trenches 74 in FIGS. 7 and 8 (not shown). This may be followed by etching back conductive material 82 from trenches 74 and within tiers 13 and 15 to produce the illustrated construction. Regardless, and in one embodiment, top gate 30t is part of one of a plurality of top horizontal conductive access lines WLt and bottom gate 30b is part of one of a plurality of bottom horizontal conductive access lines WLb, with the one top horizontal conductive access line WLt and the one bottom horizontal conductive access line WLb together directly electrically coupling together multiple of top gates 30t and bottom gates 30b of different ones of the horizontal transistors (not-yet-completed) that are in the same memory-cell tier 22.

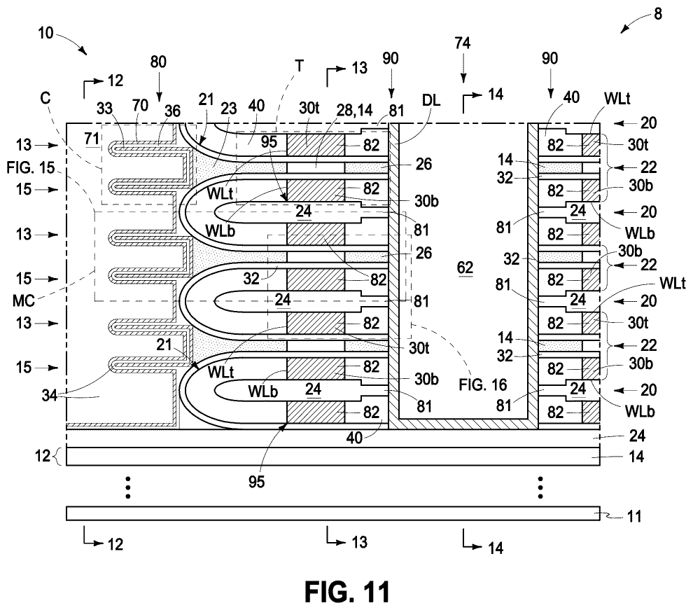

Referring to FIGS. 11-16, subsequent processing has been conducted to form construction/memory circuitry 8 comprising memory cells MC. For example, remaining silicon-germanium material 19 (not shown) has been removed as has semiconductor material 14 on capacitor side 80. Capacitors C have then been formed and that are electrically coupled with individual horizontal transistors T on capacitor side 80. Digitlines DL have also been formed and that are electrically coupled with individual horizontal transistors T on digitline side 90. Capacitors C and digitlines DL may be formed in any order relative one another. More memory-cell tiers 22 and insulative tiers 20 are shown in FIGS. 11-15 than in FIGS. 3-10 for clarity. Likely many more such tiers (e.g., dozens, hundreds, etc.) than shown would likely be included.

Individual horizontal transistors T comprise a first source/drain region 23 (e.g., formed by conductively doping material 14 from capacitor side 80 after removing materials 19 and 14 therefrom and before forming capacitors C), a second source/drain region 26 (e.g., formed by conductively doping material 14 from digitline side 90 before forming digitlines DL), and a channel region 28, 14 horizontally between first and second source/drain regions 23 and 26. Regions 23, 26, and 28 of different immediately-horizontally-adjacent memory cells MC into and out of the plane of the page upon which FIG. 11 lies in a common memory-cell tier 22 may be isolated relative one another by insulative material (not shown). Horizontal transistors T also individually comprise gate 30* (e.g., gate-all-around the channel) having gate insulator 32 (e.g., dielectric or ferroelectric) between at least channel region 28 and gate 30*. An example insulator material (e.g., 40) is laterally against lateral sides/edges of gates 30* on digitline side 90.

Example capacitors C individually comprises a first capacitor electrode 33 (e.g., a storage-node electrode), a second capacitor electrode 34 (e.g., comprising conductive metal material 70 and conductively-doped polysilicon 71), and a capacitor insulator 36 there-between (e.g., dielectric or ferroelectric). Example second capacitor electrodes 34 of multiple capacitors C are directly electrically coupled with one another. Example first capacitor electrode 33 is directly coupled to first source/drain region 23 of horizontal transistor T. Digitlines DL extend through vertically-alternating tiers 20 and 22. Individual second source/drain regions 26 of individual transistors T that are in different memory-cell tiers 22 are directly electrically coupled to individual digitlines DL. Example insulator material 62 (e.g., silicon dioxide and/or silicon nitride) is between immediately-adjacent digitlines DL.

Alternate embodiment constructions may result from method embodiments described above, or otherwise. Regardless, embodiments of the invention encompass circuitry independent of method of manufacture. Nevertheless, such circuitry arrays may have any of the attributes as described herein in method embodiments. Likewise, the above-described method embodiments may incorporate, form, and/or have any of the attributes described with respect to device embodiments.

In one embodiment, memory circuitry (e.g., 8) comprises vertically-alternating insulative tiers (e.g., 20) and memory-cell tiers (e.g., 22). Memory cells (e.g., MC) in the memory cell tiers individually comprise a horizontal transistor (e.g., T) having a gate (e.g., 30*), a capacitor side (e.g., 80), and a digitline side (e.g., 90). The capacitor is electrically coupled with the horizontal transistor on the capacitor side. A digitline (e.g., DL) is electrically coupled with the horizontal transistor on the digitline side. The gate comprises a top gate (e.g., 30t) that is part of one of a plurality of top horizontal conductive access lines (e.g., WLt) and a bottom gate (e.g., 30b) that is part of one of a plurality of bottom horizontal conductive access lines (e.g., WLb). The one top horizontal conductive access line and the one bottom horizontal conductive access line together directly electrically couple together multiple of the top and bottom gates of different ones of the horizontal transistors that are in the same memory-cell tier. The insulative tiers comprise an insulative material (e.g., 24*) that is vertically between the top gate and the bottom gate of immediately-vertically-adjacent of the memory-cell tiers. The insulative material extends laterally beyond the digitline side and the capacitor side of the top and bottom gates of the immediately-vertically-adjacent memory cells. The insulative material is vertically thinnest laterally outward of the digitline side of the top and bottom gates of the immediately-vertically-adjacent memory cells than at the capacitor side (i.e., at location 95 in FIGS. 9, 11, 15, and 16) of the top and bottom gates of the immediately-vertically-adjacent memory cells. Any other attribute(s) or aspect(s) as shown and/or described herein with respect to other embodiments may be used.

In one embodiment, memory circuitry (e.g., 8) comprises vertically-alternating insulative tiers (e.g., 20) and memory-cell tiers (e.g., 22). Memory cells (e.g., MC) in the memory cell tiers individually comprise a horizontal transistor (e.g., T) having a gate (e.g., 30*, and regardless of whether having a top and bottom gate), a capacitor side (e.g., 80), and a digitline side (e.g., 90). The capacitor is electrically coupled with the horizontal transistor on the capacitor side. A digitline (e.g., DL) is electrically coupled with the horizontal transistor on the digitline side. The insulative tiers comprise an insulative material (e.g., 24*) that is vertically between immediately-vertically-adjacent of the memory-cell tiers. The insulative material extends laterally beyond the digitline side and the capacitor side of the gates of immediately-vertically-adjacent of the memory cells. The insulative material is vertically thinnest laterally outward of the digitline side of the gates than at the capacitor side (i.e., at location 95 in FIGS. 9, 11, 15, and 16) of the gates. Any other attribute(s) or aspect(s) as shown and/or described herein with respect to other embodiments may be used.

In one embodiment, a vertically-thinnest portion of insulative material 24* that is laterally outward of digitline side 90 of gates 30* (e.g. top and bottom gates 30t and 30b) is 5% to 80%, in one embodiment 10% to 70%, and in one embodiment 25% to 60%, of vertical thickness of insulative material 24* at capacitor side 80 of gates 30* (i.e., at location 95 in FIGS. 9, 11, 15, and 16).

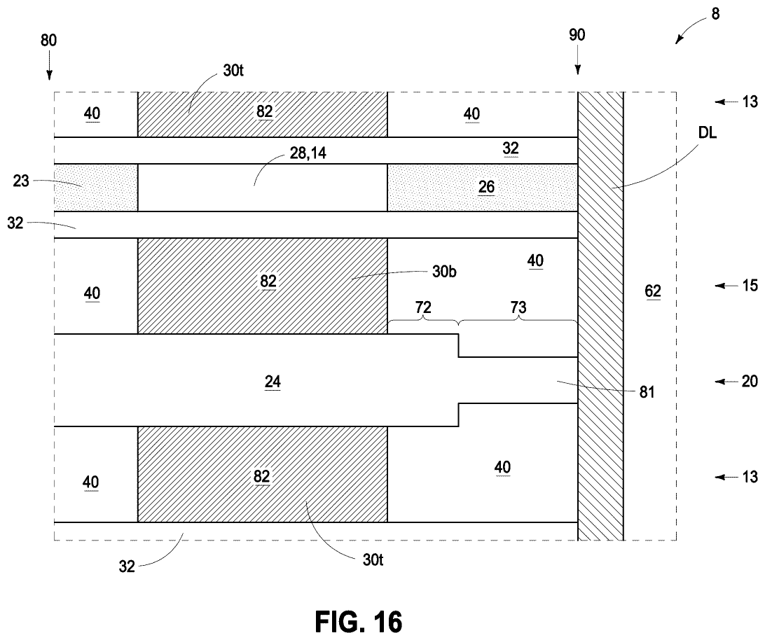

In one embodiment and as shown, insulative material 24* that is laterally outward of digitline side 90 of gates 30* has a vertically-thicker portion 72 and a vertically-thinner portion 73 (FIG. 16), with vertically-thicker portion 72 being more proximate digitline side 90 of gates 30* than vertically-thinner portion 73. In one such embodiment and also as shown, vertically-thicker portion 72 has a maximum-vertical thickness that is the same as a maximum-vertical thickness of insulative material 24* at capacitor side of gates 30* (i.e., at location 95 in FIGS. 9, 11, 15, and 16).

It will be apparent, at least with respect to method embodiments, that length of the vertically thinnest portion of insulative material 24* on digitline side 90 of gates 30* will depend on one and/or both of degree of lateral recess of insulator material 40 in FIGS. 7 and 8 and degree of lateral recess of conductive material 82 in FIGS. 9 and 10. Further, and regardless, FIGS. 5 and 6 show a vertical stepped reduction in vertical thickness of insulative material 24* on digitline side 90 of insulator material 40. Alternate profiles may of course be used or occur, for example curved concave, curved convex, straight gradual, a combination of straight and curved segments, a combination of differently angle straight segments, a combination of differently curved segments, etc.

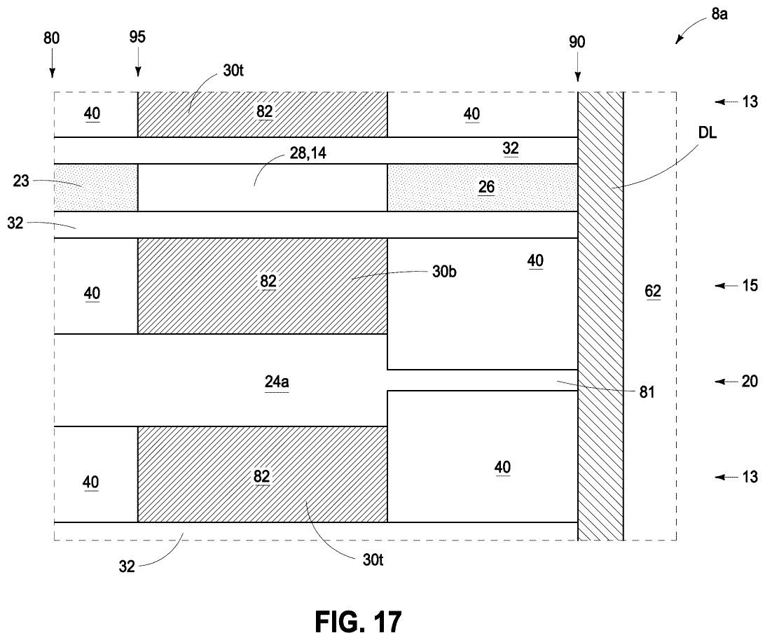

An alternate embodiment construction 8a is shown in FIG. 17 (analogous in size, scale, and position as FIG. 16). Like numerals from the above-described embodiments have been used where appropriate, with some construction differences being indicated with the suffix “a” or with different numerals. Insulative material 24a that is laterally outward of digitline side 90 of gates 30* is vertically thinner everywhere than insulative material 24a that is at capacitor side 80 of gates 30* (i.e., at location 95 in FIG. 17). Any other attribute(s) or aspect(s) as shown and/or described herein with respect to other embodiments may be used.

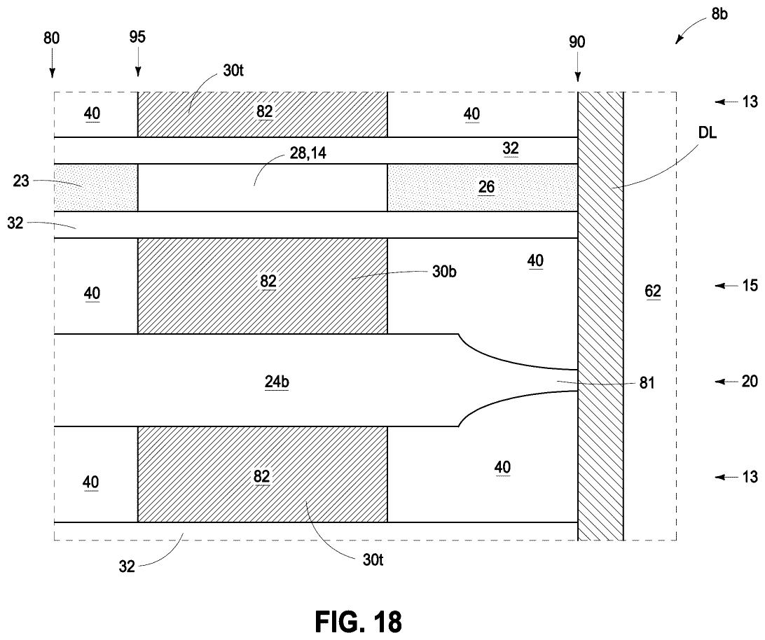

By way of examples only, alternate embodiment constructions 8b, 8c, 8d, and 8e are shown in FIGS. 18, 19, 20, and 21, respectively, comprising insulative material 24b, 24c, 24d, and 24e, respectively. Like numerals from the above-described embodiments have been used where appropriate, with some construction differences being indicated with the suffixes “b”, “c”, “d”, and “e”, respectively. Other profiles for portion 81 of insulative 24* may result or be used, for example as identified above. In one embodiment, insulative material 24* that is vertically between gates 30* has an average vertical thickness that is less than vertical thickness of insulative material 24* at capacitor side 80 of gate 30* (e.g., constructions 8d and 8e). In one embodiment, insulative material 24* that is vertically between gates 30* has a vertical thickness that reduces from capacitor side 80 of gates 30* to digitline side 90 of gates 30* (e.g., construction 8e). Any other attribute(s) or aspect(s) as shown and/or described herein with respect to other embodiments may be used.

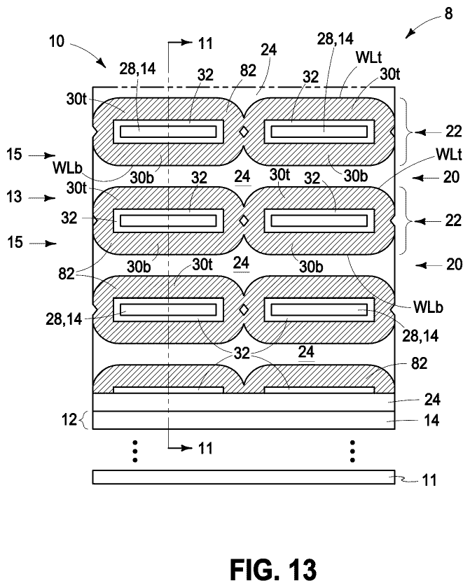

Some embodiments of the invention were motivated in reducing existence or volume void spaces in conductive material 82 in access lines WL*. FIG. 13 shows a small void space in conductive material 82 between immediately-laterally-adjacent channel-material/regions 14, 28. In method embodiments, those void spaces may individually be larger in the absence of thinning material 24* to form thinner portions 81, thus undesirably reducing volume of conductive material 82 in access lines WL* in the absence of method embodiments.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, processor communication modems, modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### CONCLUSION

In some embodiments, a method used in forming memory circuitry comprises forming vertically-alternating insulative tiers and memory-cell tiers. Memory cells of the memory-cell tiers individually comprise a horizontal transistor having a top gate, a bottom gate, a capacitor side, and a digitline side in a finished memory-circuitry construction. The insulative tiers comprise an insulative material that is vertically between a top-gate tier and a bottom-gate tier of immediately-vertically-adjacent of the memory-cell tiers. The bottom-gate tier and the top-gate tier comprise insulator material of different composition from that of the insulative material and have the insulative material vertically there-between. The insulative material projects laterally beyond digitline-side edges of the insulator material. That portion of the insulative material that is laterally projecting beyond the digitline-side edges of the insulator material is removed to reduce its vertical thickness. After the removing, the insulator material is laterally recessed toward the capacitor side selectively relative to the insulative material. After the laterally recessing, conductive material is formed in the top-gate tier and in the bottom-gate tier of the immediately-vertically-adjacent memory-cell tiers to form the top and bottom gates of the horizontal transistor. A capacitor is formed that is electrically coupled with the horizontal transistor on the capacitor side and a digitline is electrically coupled with the horizontal transistor on the digitline side.

In some embodiments, memory circuitry comprises vertically-alternating insulative tiers and memory-cell tiers. Memory cells in the memory cell tiers individually comprise a horizontal transistor having a gate, a capacitor side, and a digitline side. The capacitor is electrically coupled with the horizontal transistor on the capacitor side. A digitline is electrically coupled with the horizontal transistor on the digitline side. The insulative tiers comprise an insulative material that is vertically between immediately-vertically-adjacent of the memory-cell tiers. The insulative material extends laterally beyond the digitline side and the capacitor side of the gates of immediately-vertically-adjacent of the memory cells. The insulative material is vertically thinnest laterally outward of the digitline side of the gates than at the capacitor side of the gates.

In some embodiments, memory circuitry comprises vertically-alternating insulative tiers and memory-cell tiers. Memory cells in the memory cell tiers individually comprise a horizontal transistor having a gate, a capacitor side, and a digitline side. The capacitor is electrically coupled with the horizontal transistor on the capacitor side. A digitline is electrically coupled with the horizontal transistor on the digitline side. The gate comprises a top gate that is part of one of a plurality of top horizontal conductive access lines and a bottom gate that is part of one of a plurality of bottom horizontal conductive access lines. The one top horizontal conductive access line and the one bottom horizontal conductive access line together directly electrically couples together multiple of the top and bottom gates of different ones of the horizontal transistors that are in the same memory-cell tier. The insulative tiers comprise an insulative material that is vertically between the top gate and the bottom gate of immediately-vertically-adjacent of the memory-cell tiers. The insulative material extends laterally beyond the digitline side and the capacitor side of the top and bottom gates of the immediately-vertically-adjacent memory cells. The insulative material is vertically thinnest laterally outward of the digitline side of the top and bottom gates of the immediately-vertically-adjacent memory cells than at the capacitor side of the top and bottom gates of the immediately-vertically-adjacent memory cells.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry, the method comprising:
forming vertically-alternating insulative tiers and memory-cell tiers; memory cells of the memory-cell tiers individually comprising a horizontal transistor having a top gate, a bottom gate, a capacitor side, and a digitline side in a finished memory-circuitry construction; the insulative tiers comprising an insulative material that is vertically between a top-gate tier and a bottom-gate tier of immediately-vertically-adjacent of the memory-cell tiers, the bottom-gate tier and the top-gate tier comprising insulator material of different composition from that of the insulative material and having the insulative material vertically there-between, the insulative material projecting laterally beyond digitline-side edges of the insulator material;
removing that portion of the insulative material that is laterally projecting beyond the digitline-side edges of the insulator material to reduce its vertical thickness;
after the removing, laterally recessing the insulator material toward the capacitor side selectively relative to the insulative material;
after the laterally recessing, forming conductive material in the top-gate tier and in the bottom-gate tier of the immediately-vertically-adjacent memory-cell tiers to form the top and bottom gates of the horizontal transistor; and
forming a capacitor electrically coupled with the horizontal transistor on the capacitor side and a digitline electrically coupled with the horizontal transistor on the digitline side.

2. The method of claim 1 wherein a vertically-thinnest portion of the insulative material that is laterally outward of the digitline side of the top and bottom gates is 5% to 80% of vertical thickness of the insulative material at the capacitor side of the top and bottom gates.

3. The method of claim 2 wherein a vertically-thinnest portion of the insulative material that is laterally outward of the digitline side of the top and bottom gates is 10% to 70% of vertical thickness of the insulative material at the capacitor side of the top and bottom gates.

4. The method of claim 3 wherein the vertically-thinnest portion of the insulative material that is laterally outward of the digitline side of the top and bottom gates is 25% to 60% of vertical thickness of the insulative material at the capacitor side of the top and bottom gates.

5. The method of claim 1 wherein the insulative material that is laterally outward of the digitline side of the top and bottom gates has a vertically-thicker portion and a vertically-thinner portion, the vertically-thicker portion being more proximate the digitline side of the top and bottom gates than the vertically-thinner portion.

6. The memory circuitry of method of claim 5 wherein the vertically-thicker portion has a maximum-vertical thickness that is the same as a maximum-vertical thickness of the insulative material at the capacitor side of the top and bottom gates.

7. The method of claim 1 wherein the insulative material that is laterally outward of the digitline side of the top and bottom gates of the immediately-vertically-adjacent memory-cell tiers is vertically thinner everywhere than the insulative material that is at the capacitor side of the top and bottom gates of the immediately-vertically-adjacent memory-cell tiers.

8. The method of claim 7 wherein the insulative material that is vertically between the top and bottom gates of the immediately-vertically-adjacent memory-cell tiers has an average vertical thickness that is less than vertical thickness of the insulative material at the capacitor side of the top and bottom gates of the immediately-vertically-adjacent memory-cell tiers.

9. The method of claim 8 wherein the insulative material that is vertically between the top and bottom gates of the immediately-vertically-adjacent memory-cell tiers has a vertical thickness that reduces from the capacitor side of the gates to the digitline side of the top and bottom gates of the immediately-vertically-adjacent memory-cell tiers.

10. Memory circuitry comprising:
vertically-alternating insulative tiers and memory-cell tiers, memory cells in the memory cell tiers individually comprising a horizontal transistor having a gate, a capacitor side, and a digitline side; a capacitor being electrically coupled with the horizontal transistor on the capacitor side, a digitline electrically coupled with the horizontal transistor on the digitline side; and
the insulative tiers comprising an insulative material that is vertically between immediately-vertically-adjacent of the memory-cell tiers, the insulative material extending laterally beyond the digitline side and the capacitor side of the gates of immediately-vertically-adjacent of the memory cells, the insulative material being vertically thinnest laterally outward of the digitline side of the gates than at the capacitor side of the gates.

11. The memory circuitry of claim 10 wherein a vertically-thinnest portion of the insulative material that is laterally outward of the digitline side of the gates is 5% to 80% of vertical thickness of the insulative material at the capacitor side of the gates.

12. The memory circuitry of claim 11 wherein the vertically-thinnest portion of the insulative material that is laterally outward of the digitline side of the gates is 10% to 70% of vertical thickness of the insulative material at the capacitor side of the gates.

13. The memory circuitry of claim 12 wherein the vertically-thinnest portion of the insulative material that is laterally outward of the digitline side of the gates is 25% to 60% of vertical thickness of the insulative material at the capacitor side of the gates.

14. The memory circuitry of claim 10 wherein the insulative material that is laterally outward of the digitline side of the gates has a vertically-thicker portion and a vertically-thinner portion, the vertically-thicker portion being more proximate the digitline side of the gates than the vertically-thinner portion.

15. The memory circuitry of claim 14 wherein the vertically-thicker portion has a maximum-vertical thickness that is the same as a maximum-vertical thickness of the insulative material at the capacitor side of the gates.

16. The memory circuitry of claim 10 wherein the insulative material that is laterally outward of the digitline side of the gates is vertically thinner everywhere than the insulative material that is at the capacitor side of the gates.

17. The memory circuitry of claim 16 wherein the insulative material that is vertically between the gates has an average vertical thickness that is less than vertical thickness of the insulative material at the capacitor side of the gate.

18. The memory circuitry of claim 17 wherein the insulative material that is vertically between the gates has a vertical thickness that reduces from the capacitor side of the gates to the digitline side of the gates.

19. The memory circuitry of claim 10 wherein the insulative material that is vertically between the gates has a constant vertical thickness that is the same as vertical thickness of the insulative material at the capacitor side of the gates.

20. Memory circuitry comprising:
vertically-alternating insulative tiers and memory-cell tiers, memory cells in the memory cell tiers individually comprising a horizontal transistor having a gate, a capacitor side, and a digitline side; a capacitor being electrically coupled with the horizontal transistor on the capacitor side, a digitline electrically coupled with the horizontal transistor on the digitline side;
the gate comprising a top gate that is part of one of a plurality of top horizontal conductive access lines and a bottom gate that is part of one of a plurality of bottom horizontal conductive access lines, the one top horizontal conductive access line and the one bottom horizontal conductive access line together directly electrically coupling together multiple of the top and bottom gates of different ones of the horizontal transistors that are in the same memory-cell tier; and
the insulative tiers comprising an insulative material that is vertically between the top gate and the bottom gate of immediately-vertically-adjacent of the memory-cell tiers, the insulative material extending laterally beyond the digitline side and the capacitor side of the top and bottom gates of the immediately-vertically-adjacent memory cells, the insulative material being vertically thinnest laterally outward of the digitline side of the top and bottom gates of the immediately-vertically-adjacent memory cells than at the capacitor side of the top and bottom gates of the immediately-vertically-adjacent memory cells.
